(19) United States
(12) Patent Application Publication
(10) Pub. No.: US 2003/0138710 A1
(43) Pub. Date: Jul. 24, 2003

(54) Method of controlling photoresist stripping process and regenerating photoresist stripper composition based on near infrared spectrometer

(76) Inventors: Mi-Sun Park, Kyungki-do (KR); Jong-Min Kim, Kyungki-do (KR); Tae-Joon Park, Kyungki-do (KR); Cheol-Woo Kang, Kyungki-do (KR); Yoon-Gil Yim, Kyungki-do (KR)

Correspondence Address: STAAS & HALSEY LLP, 700 11TH STREET, NW, SUITE 500, WASHINGTON, DC, 20001, US

(21) Appl. No.: 10/276,714

(22) PCT Filed: Mar. 27, 2001
(86) PCT No.: PCT/KR01/00489

(30) Foreign Application Priority Data
Dec. 30, 2000 (KR) 2000/87140

(51) Int. Cl. G03F 7/42

(52) U.S. Cl. 430/30; 430/398

(57) ABSTRACT

In a method of controlling a photoresist stripping process for fabricating a semiconductor device or a liquid crystal display device, the composition of the stripper used in stripping the photoresist layer is first analyzed with the NIR spectrometer. The state of the stripper is then determined by comparing the analyzed composition with the reference composition. In case the life span of the stripper comes to an end, the stripper is replaced with a new stripper. By contrast, in case the life span of the stripper is left over, the stripper is delivered to the next photoresist stripping process. This analysis technique may be applied to the photoresist stripper regenerating process in a similar way.

### BACKGROUND OF THE INVENTION

(a) Field of the Invention

The present invention relates to a method of controlling photoresist stripping process and a method of regenerating a photoresist stripper composition based on a near infrared (NIR) spectrometer and, more particularly, to an NIR spectrometer-based photoresist stripping process control method and photoresist stripper composition regeneration method which automatically analyzes the composition of the stripper used in the lithography process for fabricating a semiconductor device or a liquid crystal display device in real time, thereby controlling the stripping process and regenerating the stripper in an accurate and effective manner while reducing the required period of time therefor.

(b) Description of the Related Art

As a large-size semiconductor device or liquid crystal display device becomes to be the choice of electronic consumers, the amount of solvents used in fabricating such a device has been significantly increased. In this situation, effective use of the solvents should be made to optimize the device fabrication process. Among such solvents, photoresist stripper is used to eliminate or discard a photoresist layer formed on a metallic layer of chrome or aluminum. As the stripper, inorganic acid solution, inorganic base solution, and organic solvent are generally used. Examples of the organic solvent type stripper includes a stripper consisting of aromatic hydrocarbon and alkylbenzene sulfonic acid (Japanese Patent Laid-open Publication No. 64-42653), a stripper consisting of alkanol amine, ethylene oxide additives of polyalkylene polyamine, sulfonate salt, glycolmonoalkylether (Japanese Patent Laid-open Publication No. 62-49355), and a stripper comprising aminoalcohol of less than 50% (Japanese Patent Laid-open Publication No. 64-81419 and 64-81950),

After stripping the photoresist layer, the stripper is recovered, and re-used in the next stripping process. As the photoresist stripper is repeatedly used, alien materials are continuously incorporated into the stripper, and the initial composition of the stripper is continuously altered. When such an alteration degree in the initial composition exceeds the critical value, the stripper cannot be used for the stripping purpose without adjusting the composition. In this case, the alien materials (impurities) should be removed from the stripper, and the components of the stripper exhausted through the stripping process should be newly supplied thereto. That is, the stripper should be regenerated before it is reused in the next stripping process.

Meanwhile, a conventional way of determining whether the photoresist stripper can be still used for the stripping purpose is to observe whether spots or stains are formed on a substrate during the stripping process, thereby identifying the degree of contamination and variation in the composition of the stripper. However, with such a technique, the stripper cannot be analyzed quantitatively and suitably. That is, either the stripper to be waste-disposed may be used for the stripping while causing process failure, or the stripper to be reused may be waste-disposed.

In the regeneration process of the photoresist stripper, the composition of the stripper should be analyzed from time to time to regenerate the stripper of a uniform composition. For this purpose, conventionally, the user himself extracts a sample from the regenerator, and analyzes the sample with various analytical instruments. However, this method needs much time and effort for the analysis. Furthermore, when the required components determined by the time-consuming analysis are supplied to the regenerator, the regenerator is liable to be full of the photoresist stripper due to the stripper delivered from the stripping process. In this case, part of the photoresist stripper should be discharged from the regenerator to supply the required components thereto. Consequently, the operation of the regenerator is discontinuously made, resulting in increased production cost and time.

Furthermore, as shown in the following table 1, in order to analyze various components of the stripper, separate, should be used for each component, and the concentration of the sample should be adjusted to be suitable for each analytic instrument, and more than thirty minutes is required for the analysis. This makes it difficult to perform the desired real-time analysis.

TABLE 1

| | Organic solvents | | |
|---|---|---|---|
| | (monoethanol | | |
| Component to be analyzed | amine etc.) | Photoresist | Water |
| Analytical instrument | Gas | UV-visible | Karl-Fisher |
| | chromatography | spectrophotometer | titrator |
| Standard deviation of the | Less than 0.3% | Less than 0.02% | Less than |
| analysis (error %) | | | 0.01% |
| Time for analysis | 30-40 min | 5 min | 5-10 min |
| Pre-treating of the sample | Not-required | Required | Not- |
| | | | required |

In order to overcome such problems, it has been recently proposed that an on-line analytic equipment should be used for such an photoresist stripper analysis. However, the currently available on-line analytic equipment at best makes automatic sampling so that the desired real-time stripper analysis cannot be achieved. Furthermore, with the currently available on-line analytic equipment, collective information for treating and processing the stripper used in the lithography process cannot be obtained in real time. Therefore, there is a demand for a technique where the composition of the photoresist stripper can be analyzed in real time, and the photoresist stripper should be appropriately treated on the basis of the analysis.

### SUMMARY OF THE INVENTION

It is an object of the present invention to provide a method of controlling a photoresist stripping process which can detect variation in the composition of the photoresist stripper and concentration of photoresist impurities in the stripper in real time during the process of fabricating a semiconductor device or a liquid crystal display device to manage the life span of the stripper.

It is another object of the present invention to provide a method of controlling a photoresist stripping process which can provide a standard value for the regeneration time or the waste-disposal time of the stripper to improve efficiency in use of the stripper while reducing device production cost.

It is still another object of the present invention to provide a method of regenerating an photoresist stripper which can analyze composition of the stripper in real time, and control the amount and ratio of the raw materials to be supplied to a regenerator, thereby obtaining the desired photoresist stripper having a suitable and uniform composition.

It is still another object of the present invention to provide a method of controlling a photoresist stripping process and a method of regenerating an photoresist stripper, which can simultaneously analyze various components of the stripper for a short period of time during the process of fabricating a semiconductor device or a liquid crystal display device, resulting in enhanced analytic efficiency, rapid processing, and improved quality control.

These and other objects may be achieved by a method of controlling a photoresist stripping process and a method of regenerating an photoresist stripper based on a near infrared (NIR) spectrometer.

In the photoresist stripping process controlling method, the composition of the photoresist stripper are first analyzed using the NIR spectrometer. The life span of the stripper is then identified by comparing the analyzed composition with reference composition. In case the life span of the stripper comes to an end, the stripper is replaced with a new stripper. By contrast, in case the life span of the stripper is left over, the stripper is reused in the next photoresist stripping process.

In the photoresist stripper regenerating process, the composition of the stripper in a regenerator for adjusting the composition of the stripper, are first analyzed with the NIR spectrometer. The components to be newly supplied are then identified through comparing the analyzed composition with reference composition. The required components are supplied into the regenerator.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or the similar components, wherein:

FIG. 1 is a block diagram showing the system for controlling a photoresist stripping process utilizing a NIR spectrometer according to a preferred embodiment of the present invention;

FIG. 2 is a block diagram showing the system for regenerating the photoresist stripper utilizing a NIR spectrometer according to a preferred embodiment of the present invention;

FIG. 3 is a graph for showing an example of the light absorption spectrum of a photoresist stripper in the wavelength region of 900-1700 nm measured by the NIR spectrometer, respectively;

FIG. 4 is a graph showing the relation of the true concentration of monoethanol amine in a photoresist stripper obtained by gas chromatography analysis and the concentration of the same obtained by the NIR spectrometer;

FIG. 5 is a graph showing the relation of the true concentration of N-methylpyrrolidone in a photoresist stripper obtained by gas chromatography analysis and the concentration of the same obtained by the NIR spectrometer;

FIG. 6 is a graph showing the relation of the true concentration of butyldiglycol diethylether in a photoresist stripper obtained by gas chromatography analysis and the concentration of the same obtained by the NIR spectrometer;

FIG. 7 is a graph showing the relation of the true concentration of photoresist in a photoresist stripper obtained by UV spectrometer analysis and the concentration of the same obtained by the NIR spectrometer; and

FIG. 8 is a graph showing the relation of the true concentration of water in a photoresist stripper obtained by Karl-Fisher titrator analysis and the concentration of the same obtained by the NIR spectrometer.

### DETAILED DESCRIPTION OF THE PREFERRED EMBODIMENTS

Preferred embodiments of this invention will be explained with reference to the accompanying drawings.

In the process of fabricating a semiconductor device or liquid crystal display device, a photoresist stripper is sprayed onto a substrate overlaid with a patterned photoresist layer so that the photoresist layer is stripped from the substrate. At this time, the photoresist stripper containing the stripped photoresist is collected in a stripper collection tank placed below the substrate. When the amount of the stripper in the collection tank reaches a predetermined value, it is delivered to a stripper storage tank by a delivering pump. Since each component of the stripper has its characteristic light absorption wavelength, the composition of the stripper can be analyzed in real time by detecting the light absorption of the stripper at near infrared (NIR) wavelength range with a NIR spectrometer.

The NIR spectrometer-based analysis technique is one of real-time analysis techniques recently developed. In the latter half of the nineteen-seventies, a technique of measuring moisture and protein contents in the wheat with the NIR spectrometer was officially recognized in Canada and U.S.A. Since then, the NIR spectrometer has been used in the fields of fine chemistry, pharmacy, or petrochemical plant operation automation. For instance, there are a technique of controlling yield of olefin in olefin polymerization through analyzing hydrocarbons contents in the olefin with NIR spectrometer (Japanese Patent Laid-open Publication No. Hei2-28293), a technique of measuring components of grain in real time (U.S. Pat. No. 5,751,421), a technique of measuring the amount of isomers of hydrocarbons in real time (U.S. Pat. No. 5,717,209), and a technique of analyzing the amount of aromatic compounds in hydrocarbons in real time (U.S. Pat. No. 5,145,785).

The NIR ray used in the NIR spectrometer of the present invention is-a light having wavelength of about 700-2500 nm, preferably having frequency of 4,000-12,000 cm⁻¹ (about 830-2500 nm), which is an intermediate range between the visible ray of 12,000-25,000 cm⁻¹, and the middle infrared ray of 400-4,000 cm⁻¹. Thus, the NIR ray is lower in energy than the visible ray, but higher than the middle-infrared ray. The energy of the NIR ray is correspond to the energy of a combination band and an overtone band of molecular vibrational energies of functional groups such as —CH, —OH, and —NH. As the absorption of the NIR ray by the combination band and the overtone band is significantly weak, variation in the NIR ray absorption according to the change of the absorption intensity is smaller than that of the middle infrared absorption spectrum by 1/10-1/1000. Therefore, under the application of the NIR ray, the composition of the sample can be directly analyzed without diluting. Furthermore, due to the overlapping of a plurality of overtone bands and combination bands, and light absorption by hydrogen bonding or molecular interaction, quantitative analysis with respect to various components of the sample can be performed simultaneously. For the quantitative analysis of a multiple-components sample, the ray of NIR wavelengths, which are characteristic to the multiple-components, is radiated to the sample. Then the absorption peaks are monitored, and the concentrations of each component are derived with reference to a standard calibration curve showing the relation of concentration and light absorption of the component. In case the light absorption peaks of the respective components are overlapped, multiple regression analysis can be carried out to analyze the effect of each component. Accordingly, the analysis based on the NIR spectrometer can be rapidly carried out in 1 minute or less even if several components are analyzed simultaneously.

In order to analyze the composition of the photoresist stripper in real time with the NIR spectrometer, various techniques can be used. For instance, NIR ray absorption of the sample can be measured by dipping a detection probe into a photoresist stripper storage tank or into a sample from photoresist stripper storage tank, and by detecting the light absorption of the sample in the tank. Alternatively, NIR ray absorption of the sample can be measured by flowing the photoresist stripper sample to a flow cell, and by detecting the light absorption of the flow cell.

In the technique of using the detection probe, the probe having an optical fiber cable is dipped into the stripper, and the light absorption, which are characteristic to the respective component of the stripper, are analyzed. Thereby, variations of the composition of the photoresist stripper, and variations of the concentrations of the photoresist dissolved in the stripper are detected. Since, the probe has an NIR radiation and detection parts, the probe can measure light absorption of the components at their characteristic wavelengths in real time.

In the technique of using the flow cell, the flow cell has a sampling port which is formed on a regenerator or a photoresist stripper storage tank for sampling the photoresist stripper therefrom, and the light absorption of the stripper sample is analyzed by the NIR spectrometer, thereby detecting the composition of the stripper. In the present invention, in order to analyze the composition of the stripper in real time with the NIR spectrometer, the two techniques can be selectively used to the stripping process of the semiconductor device and liquid crystal display device according to the temperature of the stripper, the amount of alien materials therein etc.

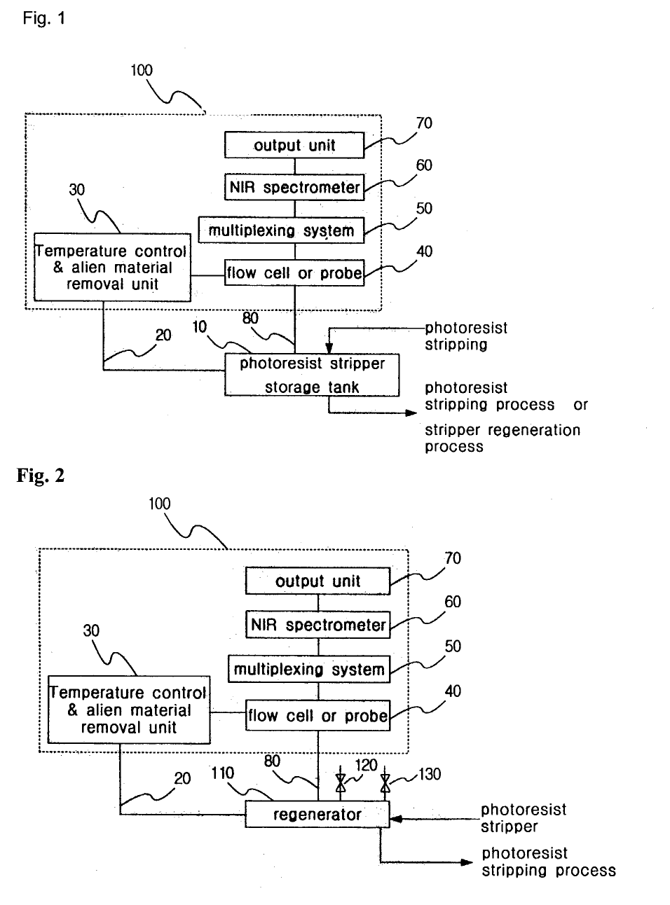

FIG. 1 is a block diagram showing an example of the system for controlling a photoresist layer stripping process utilizing a NIR spectrometer. The controlling system includes an analysis system 100, which includes a temperature control and alien material removal unit 30, a flow cell or probe 40, a multiplexing system 50, an NIR spectrometer 60 having an NIR radiation lamp, a monochromator and a detector, and an output unit 70. A tungsten-halogen lamp may be used for the NIR radiation lamp, an AOTS (acousto-optical tunable scanning), FT (Fourier transform) or a grating for the monochromator, and an indium gallium arsenic (InGaAs) or PbS detector for the detector.

In operation, a photoresist stripper sample is delivered from the storage tank 10 to the temperature control and alien material removal unit 30 via a fast loop 20. The temperature control and alien material removal unit 30 controls the sample to be at ambient temperature, and removes alien materials from the sample. Then, the sample is delivered to the flow cell or probe 40 to perform the NIR absorption analysis. Since the NIR spectrometer 60 produces different analysis results according to the temperature of the sample, the temperature of the sample should be adjusted to the same temperature with a standard sample, which is used to make a calibration curve showing the relation of concentration and absorbance. The NIR spectrometer 60 measures the absorption spectra of the sample in the flow cell or probe 40 with its NIR radiation lamp, the monochromator, and the detector. The analysis results are output by way of the output unit 70. The sample used for the analysis is delivered to the photoresist stripper storage tank 10 through a recovery system 80. As shown in FIG. 1, a multiplexing system 50 is preferably provided to change the flow cell or probe 40 analyzed by the spectrometer 60 in case one NIR spectrometer 60 is used to analyze several samples from multiple process lines. In this case, the analysis system 100 is provided with plural numbers of fast loops 20 and flow cells or probes 40 connected to the respective process lines, therefore, the samples from the multiple process lines can be analyzed with one spectrometer 60.

In order to quantitatively analyze the composition of the stripper and the photoresist contents dissolved therein, a calibration curve showing the relation of concentration and absorbance of each component should be previously made. The calibration curve is made through measuring the light absorbance of a component of a standard photoresist stripper sample while varying the concentration of the component. Then the concentration of a component in a sample can be determined by comparing the detected absorbance with the absorbance of the calibration curve, thereby identifying the composition of the sample. The analyzed composition is compared with the reference composition to determine whether the photoresist stripper should be regenerated or reused, in other word, whether the photoresist stripper is still usable.

In case the amount of each component of the stripper and the photoresist contents dissolved therein does not exceed the reference value, that is, in case the life span of the stripper does not come to an end, a separate delivering pump is operated to deliver the stripper to the next photoresist stripping process. By contrast, in case the life span of the present stripper comes to an end, a new stripper is introduced into the next photoresist layer stripping process, and the present photoresist stripper is delivered to a regenerator for regeneration of the stripper, or waste-disposed.

In this way, the composition of the stripper is automatically analyzed with a predetermined time interval using an on-line NIR spectrometer synchronized with the process lines so that the historical recording with respect to the composition of the stripper can be established, and the state of the stripper in the stripping process can be quantitatively determined. This makes it possible to use the stripper in accurate and effective manners.

A method of regenerating the photoresist stripper using a NIR spectrometer will be now explained with reference to FIG. 2. FIG. 2 is a block diagram showing the system for regenerating the photoresist stripper utilizing a NIR spectrometer. The regeneration system includes the same analysis system 100 used in the photoresist layer stripping process control system.

The method of regenerating the stripper using the NIR spectrometer utilizes the same principle as in the photoresist layer stripping process control method. The composition of the stripper in a regenerator 110 is analyzed in real time with the analysis system 100 including the NIR spectrometer 60. It is preferable that the wavelength range of the NIR spectrometer for analyzing the composition is 700-2500 nm. The analyzed compositions of the stripper are compared with the reference composition, and the components to be newly supplied are identified from the comparison. In accordance with the identification results, valves 120 and 130 are opening to supply the required components to the regenerator 110. The regenerator 110 may be operated under low pressure, high pressure, or middle pressure. In this way, the photoresist stripper is regenerated upon receipt of the required components such that it has the same composition as the initial photoresist stripper. The regenerated stripper is again fed to the photoresist stripping process.

The analysis system 100 can be connected to a controller (not shown), and the controller controls the valves 120 and 130 such that they automatically supply the required constituents according to the analysis result. In the photoresist layer stripping process, the process automation can be also applied in the same manner. The components of the stripper that can be analyzed with the NIR spectrometer include organic amine compounds such as 2-amino-1-ethanol, 1-amino-2-propanol, 2-amino-1-propanol, 3-amino-1-propanol, 2-amino-1-butanol, 4-amino-1-butanol, 2-(2-aminoethoxy)ethanol, monoethanolamine, isopropanolamine, N-methylethanolamine, N-ethylethanolamine, diethanolamine, dimethylethanolamine, triethanolamine, alkylenepolyamine incorporated with ethyleneoxide of ethylenediamine, piperidine, benzylamine, hydroxylamine, 2-methylaminoethanol et al., triazol compounds such as benzotriazol (BT), tolyltriazol (TT), carboxylic benzotriazol (CBT), 1-hydroxy benzotriazol (HBT), nitro benzotriazol (NBT) et al. Another examples of the components of the stripper that can be analyzed with the NIR spectrometer includes N,N-dimethylacetamide (DMAc), N,N-dimethylformamide (DMF), N-methylpyrrolidone (NMP), dimethylsulfoxide (DMSO), carbitol acetate, methoxyacetoxypropane, N,N-diethylacetamide (DEAc), N,N-dipropylacetamide (DPAc), N,N-dimethylpropionamide, N,N-diethylbutylamide, N-methyl-N-ethylpropionamide, 1,3-dimethyl-2-imidazolidinone (DMI), 1,3-dimethyltetrahydropyrimidinone, sulfolane, dimethyl-2-piperidone, γ-butyrolactone, ethylenegylcol monomethylether, ethylenegylcol monoethylether, ethylenegylcol monobutylether, diethylenegylcol monopropylether, propylenegylcol monomethylether, propylenegylcol monoethylether, diethyleneglycol dialkylether, catechol, saccharide, quaternary ammonium hydroxide, sorbitol, ammonium fluoride, phenol compound having 2 or 3 hydroxyl groups, alkylbenzene sulfonate, polyalkylenepolyamine additive of ethylene oxide, sulfonate salt, water et al., but not limited thereto.

The following examples are provided just to illustrate the present invention in more detail. In the examples, the percentage and the mixture ratio represent weight percent and weight ratio.

### EXAMPLES 1 TO 5

Photoresist strippers having the compositions (1) to (4) for liquid crystal display device fabrications listed below, and the photoresist stripper having the composition (5) for semiconductor fabrication were used in the photoresist stripping process control system shown in FIG. 1, and the composition of the photoresist stripper were analyzed in real time in the controlling system. The analysis was performed at various concentrations of the photoresist stripper components. The results of the analysis are compared with the analysis results obtained from the conventional analysis method, which uses various analysis instruments. Namely, in order to evaluate the adequacy of the NIR spectrometer-based analysis for the stripping process, the photoresist stripper analysis results from the NIR spectrometer were compared with the photoresist stripper analysis results from the conventional analysis system over the long time period of seven months. The comparison results are listed in Table 2 for the photoresist strippers having the compositions (1) to (4), and in Table 3 for the photoresist stripper having the composition (5).

(1) monoethanolamine, butyldiglycol diethylether, N-methylpyrrolidone, photoresist, and water

(2) monoethanolamine, butyldiglycol diethylether, photoresist, and water

(3) monoethanolamine, dimethylsulfoxide, photoresist, and water

(4) isopropanolamine, dimethylsulfoxide, photoresist, and water

(5) monoethanolamine, catechol, dimethylsulfoxide, carbitol, photoresist, and water

TABLE 2

| | Monoethanol- | N-methyl- | butyldiglycol | | |
|---|---|---|---|---|---|
| Component | amine | pyrrolidone | diethylether | photoresist | Water |
| Measurement | 5-30 wt % | 10-35 wt % | 40-70 wt % | 0-0.1 wt % | 0.1-10 |
| Range | | | | | wt % |
| Correlation | | | | | |
| coefficient (R²) | 0.997 | 0.958 | 0.994 | 0.982 | 0.993 |
| Standard | | | | | |
| deviation (SD) | 0.088 | 0.162 | 0.181 | 0.010 | 0.044 |

TABLE 3

| | Monoethanol- | Dimethyl | | |
|---|---|---|---|---|
| Component | amine | sulfoxide | photoresist | Water |
| Frequency | 4000-12000 cm⁻¹ | | | |
| Range | | | | |
| Correlation | 0.9998 | 0.9998 | 0.9951 | 0.9984 |
| coefficient (R²) | | | | |
| Standard | 0.0006 | 0.0323 | 0.0041 | 0.0055 |
| deviation (SD) | | | | |

As known from Tables 2 and 3, the correlation coefficient in measurement of the present NIR analysis system to the conventional analysis system was appeared to reach 0.999, and the standard deviation to be at maximum about 0.18. That is, the present system and the conventional system produce substantially the same analysis results, and the NIR spectrometer can analyze the small amount of photoresist accurately.

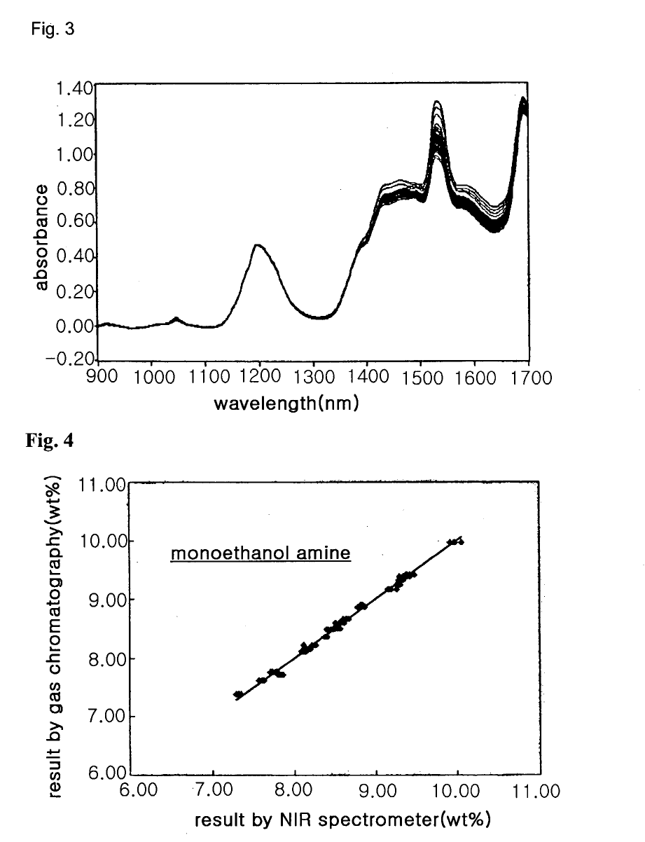

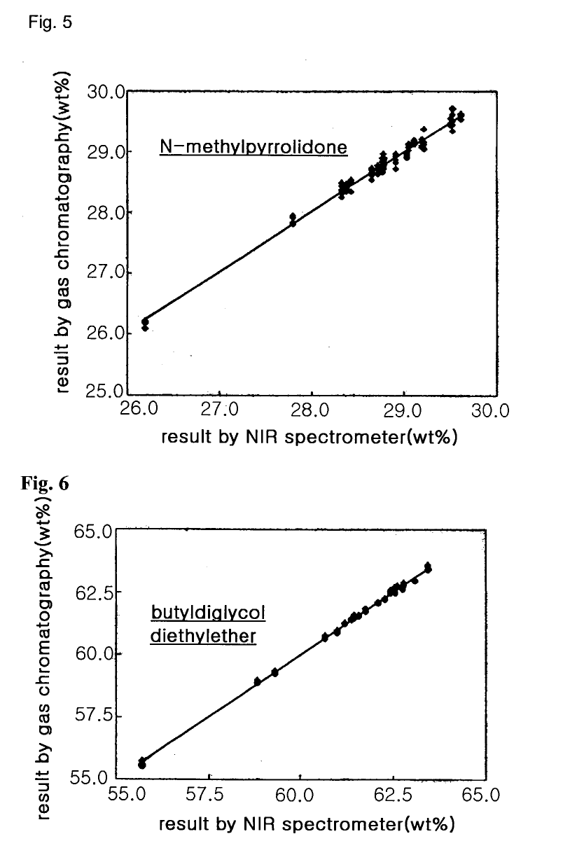

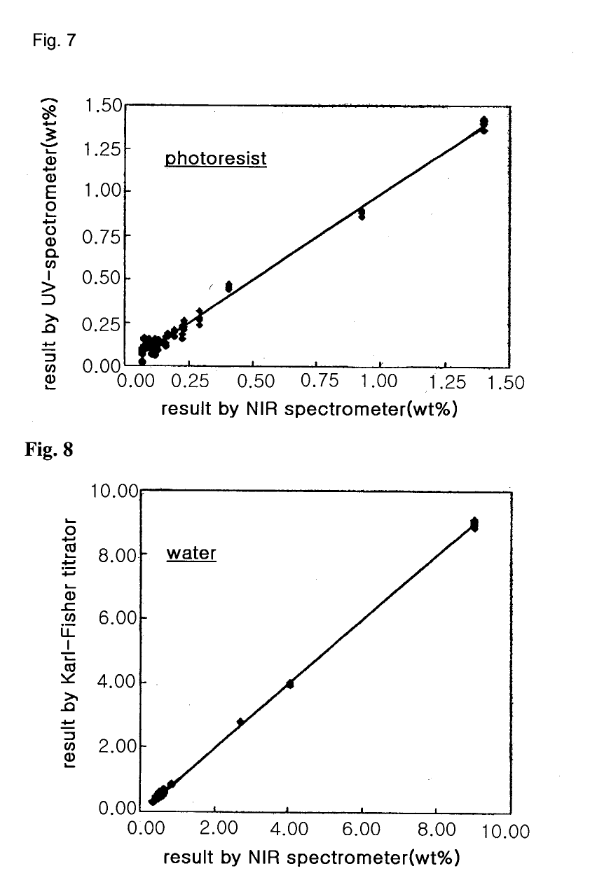

FIG. 3 is a graph for showing an example of the light absorption spectrum of the photoresist stripper (1) in the wavelength range of 900-1700 nm. FIGS. 4 to 8 are graphs showing the true concentrations of photoresist stripper components (monoethanolamine, N-methylpyrrolidone, butyldiglycol diethylether, photoresist, and water) obtained by gas chromatography, UV spectrophotometer, and Karl-Fisher titrator, and the concentrations obtained through the NIR spectrometer. As known from the graphs, the concentrations obtained by the NIR spectrometer have good correlation with respect to the true concentration determined by conventional analytical instrument.

As described above, the inventive method of controlling a photoresist stripping process and regenerating the photoresist stripper based on an NIR spectrometer makes it possible to accurately analyze the composition of the stripper used in the photoresist stripping process for fabricating a semiconductor device or a liquid crystal display device. Accordingly, the state of the stripper in the process is quantitatively analyzed so that the photoresist stripping process can be controlled in an effective manner. Furthermore, with the inventive method, the stripper used in the photoresist layer stripping process is regenerated in a reliable manner while reducing the amount of consumption of raw materials. In addition, it can be discriminated in real time whether the photoresist stripper is still usable in the process line, and this makes it possible to significantly enhance process yield.

While the present invention has been described in detail with reference to the preferred embodiments, those skilled in the art will appreciate that various modifications and substitutions can be made thereto without departing from the spirit and scope of the present invention as set forth in the appended claims.

What is claimed is:

1. A method of controlling a photoresist stripping process, the method comprising the steps of:
analyzing composition of a stripper used for stripping a photoresist layer in the process of fabricating a semiconductor device or a liquid crystal display device with a near infrared spectrometer;
determining whether the stripper is usable by comparing the analyzed composition with reference composition; and
either replacing the stripper with a new stripper in case the stripper is not usable, or using the stripper in a next photoresist stripping process in case the stripper is usable.

2. The method of claim 1 wherein the stripper includes one or more organic amine compounds selected from the group consisting of 2-amino-1-ethanol, 1-amino-2-propanol, 2-amino-1-propanol, 3-amino-1-propanol, 2-amino-1-butanol, 4-amino-1-butanol, 2-(2-aminoethoxy)ethanol, monoethanolamine, isopropanolamine, N-methylethanolamine, N-ethylethanolamine, diethanolamine, dimethylethanolamine, triethanolamine, alkylenepolyamine incorporated with ethyleneoxide of ethylenediamine, piperidine, benzylamine, hydroxylamine, and 2-methylaminoethanol.

3. The method of claim 1 wherein the stripper includes one or more triazol compounds selected from the group consisting of benzotriazol (BT), tolyltriazol (TT), carboxylic benzotriazol (CBT), 1-hydroxy benzotriazol (HBT), and nitro benzotriazol (NBT)I.

4. The method of claim 1 wherein the stripper includes one or more compounds selected from the group consisting of N,N-dimethylacetamide (DMAc), N,N-dimethylformamide (DMF), N-methylpyrrolidone (NMP), dimethylsulfoxide (DMSO), carbitol acetate, methoxyacetoxypropane, N,N-diethylacetamide DEAc), N,N-dipropylacetamide (DPAc), N,N-dimethylpropionamide, N,N-diethylbutylamide, N-methyl-N-ethylpropionamide, 1,3-dimethyl-2-imidazolidinone (DMI), 1,3-dimethyltetrahydropyrimidinone, sulfolane, dimethyl-2-piperidone, γ-butyrolactone, ethylenegylcol monomethylether, ethylenegylcol monoethylether, ethylenegylcol monobutylether, diethylenegylcol monopropylether, propylenegylcol monomethylether, propylenegylcol monoethylether, diethyleneglycol dialkylether, catechol, saccharide, quaternary ammonium hydroxide, sorbitol, ammonium fluoride, phenol compound having 2 or 3 hydroxyl groups, alkylbenzene sulfonate, polyalkylenepolyamine additive of ethylene oxide, sulfonate, and water.

5. The method of claim 1 wherein the near infrared spectrometer comprises a light source radiating a ray of wavelength range of 700-2500 nm.

6. The method of claim 1 wherein the near infrared spectrometer comprises at least one probe, the probe being dipped into a photoresist stripper storage tank to detect the light absorbance of the stripper.

7. The method of claim 1 wherein the near infrared spectrometer measures the light absorption of at least one flow cell containing the stripper delivered from a photoresist stripper storage tank.

8. The method of claim 1 wherein the step of either replacing the stripper with a new stripper or using the stripper in the next photoresist stripping process is performed automatically by a controller.

9. A method of regenerating a photoresist stripper, the method comprising the steps of:
analyzing composition of the stripper in a regenerator for adjusting the composition of the stripper with a near infrared spectrometer;
determining components to be newly supplied to the stripper by comparing the analyzed composition with reference composition; and
supplying the required components into the regenerator.

10. The method of claim 9 wherein the stripper includes one or more organic amine compounds selected from the group consisting of 2-amino-1-ethanol, 1-amino-2-propanol, 2-amino-1-propanol, 3-amino-1-propanol, 2-amino-1-butanol, 4-amino-1-butanol, 2-(2-aminoethoxy)ethanol, monoethanolamine, isopropanolamine, N-methylethanolamine, N-ethylethanolamine, diethanolamine, dimethylethanolamine, triethanolamine, alkylenepolyamine incorporated with ethyleneoxide of ethylenediamine, piperidine, benzylamine, hydroxylamine, and 2-methylaminoethanol.

11. The method of claim 9 wherein the stripper includes one or more triazol compounds selected from the group consisting of benzotriazol (BT), tolyltriazol (TT), carboxylic benzotriazol (CBT), 1-hydroxy benzotriazol (HBT), and nitro benzotriazol (NBT)I.

12. The method of claim 9 wherein the stripper includes one or more compounds selected from the group consisting of N,N-dimethylacetamide (DMAc), N,N-dimethylformamide (DMF), N-methylpyrrolidone (NMP), dimethylsulfoxide (DMSO), carbitol acetate, methoxyacetoxypropane, N,N-diethylacetamide DEAc), N,N-dipropylacetamide (DPAc), N,N-dimethylpropionamide, N,N-diethylbutylamide, N-methyl-N-ethylpropionamide, 1,3-dimethyl-2-imidazolidinone (DMI), 1,3-dimethyltetrahydropyrimidinone, sulfolane, dimethyl-2-piperidone, y-butyrolactone, ethylenegylcol monomethylether, ethylenegylcol monoethylether, ethylenegylcol monobutylether, diethylenegylcol monopropylether, propylenegylcol monomethylether, propylenegylcol monoethylether, diethyleneglycol dialkylether, catechol, saccharide, quaternary ammonium hydroxide, sorbitol, ammonium fluoride, phenol compound having 2 or 3 hydroxyl groups, alkylbenzene sulfonate, polyalkylenepolyamine additive of ethylene oxide, sulfonate, and water.

13. The method of claim 9 wherein the near infrared spectrometer comprises a light source radiating a ray of wavelength range of 700-2500 nm.

14. The method of claim 9 wherein the step of supplying the required components into the regenerator is performed automatically by a controller according to the analyzed composition of the stripper.
